(19) United States
(12) Patent Application Publication
(10) Pub. No.: US 2019/0006331 A1
(43) Pub. Date: Jan. 3, 2019

(54) ELECTRONICS PACKAGE DEVICES WITH THROUGH-SUBSTRATE-VIAS HAVING PITCHES INDEPENDENT OF SUBSTRATE THICKNESS

(71) Applicant: Intel Corporation, Santa Clara, CA (US)

(72) Inventors: Bilal Khalaf, Folsom, CA (US); John G. Meyers, Sacramento, CA (US)

(73) Assignee: Intel Corporation, Santa Clara, CA (US)

(21) Appl. No.: 15/640,279

(22) Filed: Jun. 30, 2017

(51) Int. Cl. H01L 25/10; H01L 25/065; H01L 25/00; H01L 21/48; H01L 23/31

(52) U.S. Cl. CPC H01L 25/105; H01L 25/0657; H01L 25/50; H01L 21/486; H01L 2225/1058; H01L 2225/06562; H01L 2225/06548; H01L 2225/0652; H01L 23/3128

(57) ABSTRACT

An electronics package device having a through-substrate-via comprises a substrate having a cavity and at least one electronic component (e.g., stack of dies) supported in the cavity. The electronics package device comprises a through-substrate-via disposed through the substrate and that has a pitch-to-height ratio of less than 1.5 and a pitch value that is independent of a thickness value of the substrate. Thus, the pitch of the through-substrate-via is uniform or consistent along the length of the through-substrate-via regardless of the height of the substrate. A supplemental electronics package device can be stacked on the first package device and electrically coupled to an assembly circuit board by the through-substrate-vias. A method is provided of making the electronics package device that minimizes space required for vertical interconnects for PoP devices having the electronic package device. A method is provided that maximizing an amount of input/output contacts between an assembly circuit board and the electronics package device.

### TECHNICAL FIELD

Embodiments described herein relate generally to electronics package devices with through-substrate-vias, and further to package-on-package devices with through-substrate-via connections.

### BACKGROUND

Electronic package devices can be stacked on top of one another in order to save space in an x/y direction, or for other system design reasons. Such package-on-package (PoP) devices face the challenge of providing electrical connections between non-adjoining package devices or structures. For example, a first (i.e. bottom) package device can be directly mounted on an assembly circuit board, and a second (i.e. top) package device can be directly mounted on the first package device. In such a situation, there is likely a need to provide electrical connections between the top package device and the assembly circuit board. One mechanism for providing such electrical connections is by forming vias through a mold compound portion of the bottom package device.

Through-mold-vias (TMVs) can be created by laser drilling holes through the mold compound of the bottom package device, followed by filling the holes with an electrically conductive material. A solder ball is then mounted on top of each TMV and the top package attached.

One problem caused by laser drilling the holes through the mold compound is that they have a non-uniform (e.g. conical) shape due to the nature of the materials removal process. Thus, an upper end of the TMV will have a larger cross sectional area (e.g., diameter) than that of its lower end. The result is that the TMV has a relatively high (e.g., 1.0+) height to pitch ratio, which either limits the number of overall interconnects that can be passed through the bottom package to the top package, or requires a larger overall PoP device to meet electrical requirements.

Another challenge is to fill the TMV holes with conductive material while preventing the formation of voids. This challenge only increases as thickness (z direction) of the bottom package increases.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1A illustrates a schematic side plan view of an electronics package device in accordance with an example embodiment;

FIG. 1B illustrates a schematic top plan view an electronics package device in accordance with an example embodiment;

FIG. 2 illustrates a schematic side plan view of processes of making an electronics package device in accordance with an example embodiment;

FIG. 3 illustrates a schematic side plan view of processes of making an electronics package device in accordance with an example embodiment;

FIG. 4 illustrates a schematic side plan view of processes of making a PoP device with the electronics package devices in accordance with an example embodiment;

FIG. 5 illustrates a schematic side plan view of processes of making a PoP device with the electronics package devices in accordance with an example embodiment;

FIG. 6 illustrates a flow diagram of a process for fabrication of an electronics device package in accordance with an example embodiment;

FIG. 7 illustrates a flow diagram of a process for fabrication of a POP device in accordance with an example embodiment; and

FIG. 8 illustrates a plan view of a system having an electronics package device in accordance with an example of the present disclosure.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” include express support for plural referents unless the context clearly dictates otherwise. Thus, for example, reference to “a layer” includes a plurality of such layers.

In this disclosure, “comprises,” “comprising,” “containing” and “having” and the like can have the meaning ascribed to them in U.S. patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. patent law. “Consisting essentially of” or “consists essentially of” have the meaning generally ascribed to them by U.S. patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in the written description, like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. “Directly coupled” objects, structures, or elements are in physical contact with one another. Objects described herein as being “adjacent to” each other may be in physical contact with each other, in close proximity to each other, or in the same general region or area as each other, as appropriate for the context in which the phrase is used. Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

### EXAMPLE EMBODIMENTS

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

In one example, there is provided an electronics package device having a through-substrate-via. The electronics package device comprises a substrate having a first height region and a second height region, where the first height region has a thickness value greater than a thickness value of the second height region; at least one electronic component supported by the second height region; and a through-substrate-via disposed through the first height region. The through-substrate-via has a pitch-to-height ratio of less than 1.5, and in some cases less than 1.0, and in other cases approximately 0.15. Furthermore, the pitch value of the through-substrate-via is independent of the thickness value of the first height region of the substrate.

In one example, there is provided an electronics assembly for PoP devices, comprising: an assembly circuit board; a first package device comprising a first substrate having a plurality of through-substrate-vias each having a pitch value independent of a thickness value of the substrate; and a second package device stacked on the first package device and electrically coupled to the assembly circuit board by the through-substrate-vias.

In one example, there is provided a method of making an electronics package device that minimizes space required for vertical interconnects for PoP devices. The method comprises forming a substrate having a plurality of through-substrate-via each having a pitch value independent of a thickness value of the substrate and a cavity configured to receive at least one electronic component; coupling at least one electronic component to the substrate in the cavity; and encasing the at least one electronic component with an encapsulate material.

In one example, there is provided a method for maximizing an amount of input/output contacts between an assembly circuit board and an electronics package device. The method comprises providing a first package device comprising a substrate having a plurality of through-substrate-vias each having a pitch value independent of a thickness value of the substrate; coupling lower contact pads of the through-substrate-vias to an assembly circuit board; and coupling a second package device to upper contact pads of the through-substrate-vias to electrically couple the second package device to the assembly circuit board.

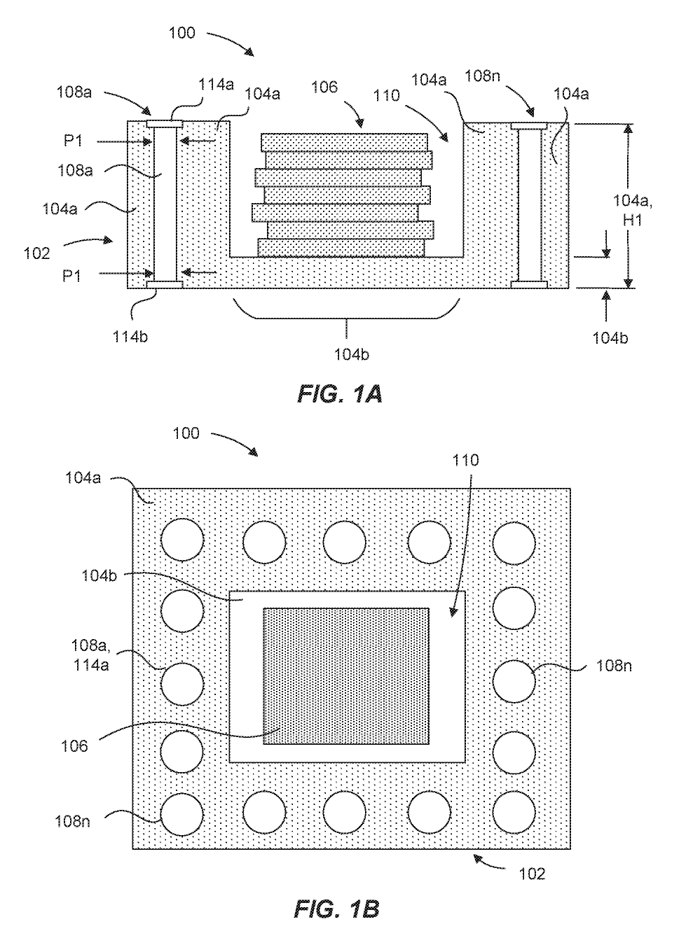

FIG. 1A illustrates a side plan view of an electronics package device 100, and FIG. 1B illustrates a top plan view of the electronics package device 100, in accordance with an example of the present disclosure. The electronics package device 100 can comprise a substrate 102 having a first height region 104a and a second height region 104b. The first height region 104a has a thickness value greater than a thickness value of the second height region 104b. For instance, the thickness value of the first height region 104a can range from approximately 0.1 mm to 1.0+ mm, and the second height region 104 can have a thickness value of less than 0.5 mm (and even less than 0.1 mm).

The electronics package device 100 comprises at least one electronic component 106 supported by the second height region 104b. In the illustrated example, the at least one electronic component 106 comprises a stack of dies, such as at least two, three, or four dies stacked on each other (or seven or more dies, in some examples). The at least one electronic component 106 can be disposed in a cavity 110 of the substrate, as further described below.

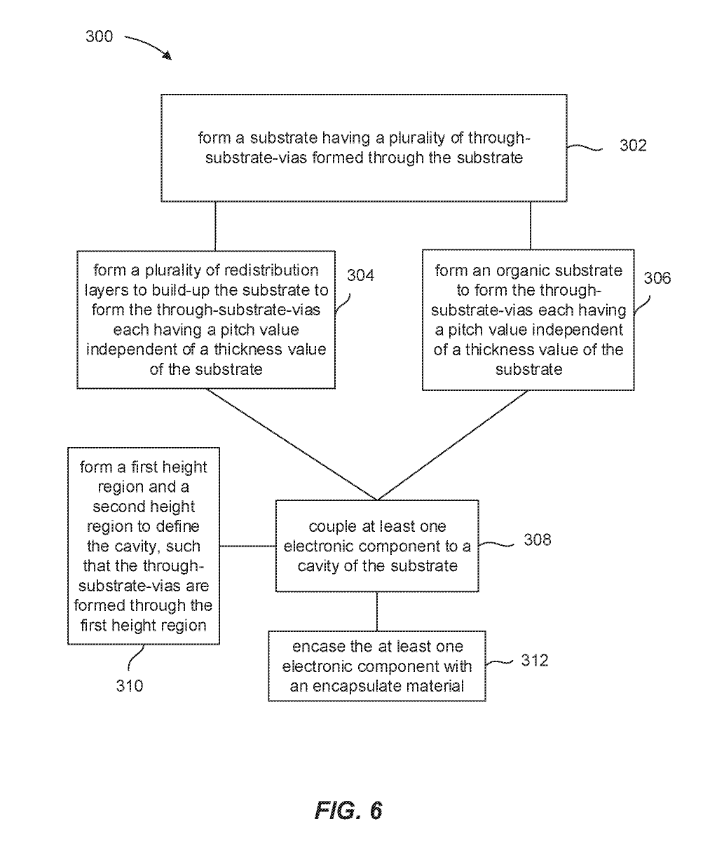

The electronics package device 100 comprises a through-substrate-via 108a disposed through the first height region 104a for electrically coupling a supplemental (e.g. second) package device (stacked above the electronics package device 100) to an assembly circuit board or other device or component supporting the electronics package device 100 (see FIG. 6). In one example, the through-substrate-via 108a comprises a pitch-to-height ratio of less than 1.0 and in some examples less than 0.2. For instance, assume a height H1 (mold cap z height) of the through-substrate-via 108a is 0.5 mm, and assume the through-substrate-via 108a has a pitch value P1 of 0.15 mm. Therefore, the pitch-to-height ratio would be 0.30 (i.e. P1/H1). In another example, assume height H1 is 1.0 mm and the through-substrate-via 108a (again) has a pitch value P1 of 0.15 mm, then the pitch-to-height ratio would be 0.15. In some embodiments, it can be desirable to have the smallest possible value of a pitch-to-height ratio to maximize electrical performance, and to efficiently use the x/y space of the package device 100 in order to maximize the input/output contacts that can be implemented though the package device 100.

It should be appreciated that the term “through-substrate-via” is not the same as “through-silicon-via” widely used in the art, and therefore should not be confused as the same or similar limitations because they have structurally different configurations, purposes, and methods of forming such. For instance, through-silicon-vias are formed about (e.g., etched) dies of a stack for interconnecting pads and other contact points to and from the dies, and pass entirely though a particular die. Thus, typically the length of such through-silicon-vias are shorter than through-substrate-vias. Moreover, through-substrate-vias are disposed through substrate materials, which have different mechanical properties than a silicon die, and that are formed by different methods, such as the RDL or organic substrate forming methods described herein. Therefore, a through-substrate-vias can be dramatically different than a through-silicon-via, for these and other reasons known in the art.

As presented by the above example, the pitch value of the through-substrate-via 108a is independent of the thickness value of the first height region 104a of the substrate 102. Thus, regardless of whether the thickness value of the first height region 104a is 0.1 mm or 1.0+ mm, the pitch value will remain the same, such as 0.15 mm up to 0.4 mm, for instance. Said another way, the through-substrate-via 108a can have a substantially constant cross-sectional area (e.g., pitch value) along its entire length. And said yet another way, the through-substrate-via 108a can have a substantially uniform diameter (e.g., pitch value) along its entire length or at least at its top and bottom portions. In any event, any particular pitch value of the through-substrate-via 108a is independent of the thickness value of the first height region 108a. That is, regardless of the thickness or height of the first height region 108a, the diameter or pitch of the through-substrate-via 108a is unaffected.

In some examples, the height of the first height region 104a can be equal to or greater than a combined height of the second height region 104b and the at least one electronics component 106 (e.g., a stack of dies). For instance, H1 of the first height region 104a can be 1 mm while the height of the second height region 104b can be 0.1 mm, and while each die is also 0.1 mm. Thus, with seven stacked dies, for instance, the total height of the first height region 104b and the dies would be approximately 0.8 mm, which is slightly less than the 1.0 mm height of the first height region 104a.

In other examples, the first height region 104a can have a top surface defining a plane that is uninterrupted by (i.e. not intersected by) any electronics components 106 in the second region 104b. In yet other examples, the electronics components 106 in height section 104b may intersect a plane defined by a top surface of the first height region 104a. In other examples, the electronic components 106 in the second height region 104b can extend to substantially within a plane defined by a top surface the first height region 104a.

In some examples, the ratio of the thickness (z-height) of the first height region 104a to the thickness of the second height region 104b is 10:1, yet in other examples it could be greater, such as 15:1 or more. Thus, the z-height of the of the first height region 104a can be 10× (or more) of the z-height of the second height region 104b, all without affecting the pitch value of the through-substrate-vias 108a-n disposed through the first height region 104a.

Accordingly, in the present disclosure, because a pitch value of each of the plurality of through-substrate-vias 108a-n is independent of the first height region 104a, many more through-substrate-vias can be formed through the substrate 102 regardless of the overall thickness of the substrate 202 (i.e., first height region 104a), because the upper pitch diameters of the through-substrate-vias 108a-n consume less area (as compared to the aforementioned TMVs that have conical shapes when laser drilled). Therefore, the electronics package device 100 has through-substrate-vias 108a-n that can maximize the amount of I/O contacts through the substrate 102 for electrically coupling a supplemental package to an assembly circuit board (i.e., a PoP device), as further exemplified below.

In one instance, the pitch value P1 is less than 0.4 mm, and in another instance, the pitch value P1 is less than 0.2 mm, such as 0.15 mm pitch. In one instance, a thickness value of the first height region 104a is at least 0.1 mm, and in another instance, said thickness value is between 0.1 mm and 1.0 mm, but it can be greater than 1.0 mm without affecting the pitch value P1.

The through-substrate-via 108a (and each through-substrate-via 108a-n) can have an upper contact pad 114a and a lower contact pad 114b for electrically coupling electrical devices together, such as another package to an assembly circuit board, as discussed further below. In one embodiment, the contact pads 114a and 114b can have a pitch of approximately 0.4 mm to achieve an optimal mechanical and electrical bond to a solder ball and another electronic device, but such pitch can be less than 0.4 mm in other embodiments.

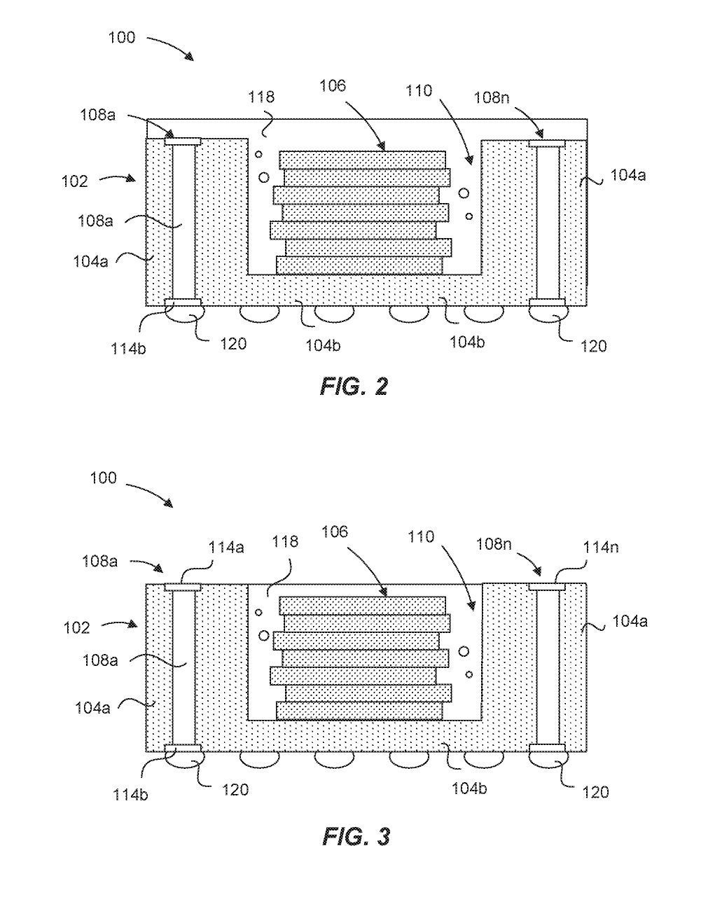

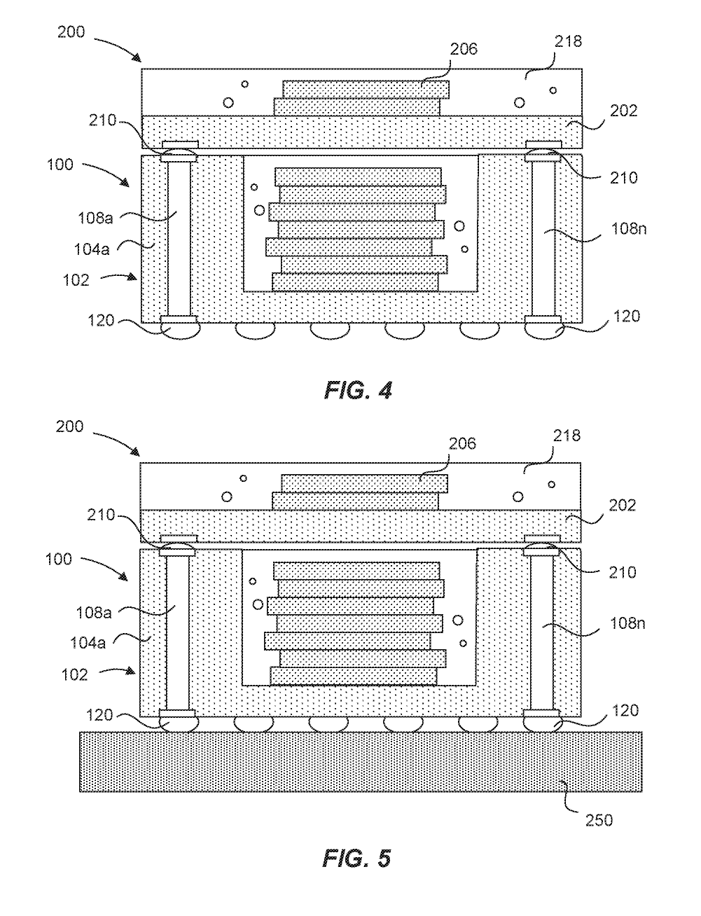

FIGS. 2 and 3 illustrate a method of making the electronics package device 200, and FIGS. 4 and 5 illustrate a method of making a PoP device with the electronics package device 100, all in accordance with examples of the present disclosure. In one example, the substrate 102 can be formed by a redistribution layering process. Such a process can allow the through-substrate vias 108a-n to be created as part of the process for building-up layers to form the substrate 102. In the present example, a plurality of layers can be built-up to form the substrate 102 and the through-substrate-vias 108a-n to form the package device 100, as shown and discussed herein. That is, substrate layers can be deposited/built in a manner to form the cavity 110 and the first and second height regions 104a and 104b, as shown on FIG. 2, while forming the conductive structures that make up the through-substrate-vias 108a-n.

For example, a plurality of metal and dielectric layers can be deposited by implementing RDL processes/machines to form the substrate 102 having the through-substrate-vias 108a-n, as shown on FIG. 1A, or formed more complex such as laterally and vertically routed through the substrate 102. For instance, an RDL process can comprise forming layers onto a base substrate/wafer or carrier panel to route I/O layout into a fine pitch footprint of interconnect vias to form and build up the substrate. Of such vias, the through-substrate-vias 108a-n can be formed with metallic or conductive material, layer by layer, along with dielectric layers that make up the first and second height regions 104a and 104b. Photoresist patterning, etching, and copper platting can be implemented, for instance, to achieve the build-up of metal layers adjacent the dielectric layers. Such RDL processes continue until the second height region 104b is formed to a desired z-height/thickness (e.g., 0.1 mm) and x/y surface area (e.g., larger than a x/y surface area of the dies). Likewise, the RDL process can continue until the desired amount of through-substrate-vias 108a-n are formed vertically through the adjacent dielectric layers that make up the first height region 104a (e.g., 1 mm height) of the substrate 102. Notably, because the RDL process is implemented in this example, the pitch of each through-substrate-via 108a-n can be controlled along the entire length of the through-substrate-via to a high degree of accuracy with an RDL machine/process as the substrate is being formed, thereby resulting in a substantially uniform and consistent pitch (e.g., diameter) regardless of, or independent of, the height of the through-substrate-via and/or the height of the first height region 104a. This is advantageous over existing methods that may use laser drilling, or that may implement processes that form via post through molds, particularly via posts that have z-height limitations through a mold due to mechanical limitations.

In an alternative example, the substrate 102 can be an organic substrate. Organic substrates are solids whose building block are pi bonded molecules or polymers made up by carbon and hydrogen, or nitrogen, sulfur, and oxygen, which exist in form of crystals or amorphous thin films, which can be used as layers to build-up or form a semiconductor substrate. Organic substrates can be created by depositing (e.g., spin coating) thin-film organic layers to build-up a substrate core, and sequentially building-up copper plating layers, all in a controlled, highly accurate manner.

Therefore, in the present example the substrate 102 can be formed via such organic substrate processes (or other organic processes) to form the substrate 102 and the through-substrate-vias 108a-n, as shown on FIG. 2. Thus, the dielectric organic layers can be deposed until a desired height and surface area of the second height region 104b is generated, while also forming the dielectric layers that make up the first height region 104b, and while depositing copper plating layers that correspond to the size and position of each through-substrate-via 108a-n. As with an RDL process, the layering of the organic and copper material continues until the final substrate package is generated, such as shown on FIG. 1A. Organic substrates can be advantageous over ceramic substrates for a variety of reasons, such as better control over dimensions when forming an organic substrate. Thus, the pitches of the through-substrate-vias 108a-n can be controlled to a high degree of accuracy, thereby resulting in a substantially uniform and consistent pitch regardless of, or independent of, the height of the particular through-substrate-via and/or the height of the first height region 104a. In some examples, an organic substrate can also be a Silicon interposer defining the cavity 110.

Whether the substrate 102 is formed by organic substrate process or redistribution layer processes, once the cavity 110 is formed/defined, then the at least one electronics component 106 can be attached (e.g., bonded) to a surface of the second height region 104b. In the example shown a plurality of dies (e.g., seven dies), are stacked in the cavity 110 and supported by the second height region 104b. Alternatively, the at least one electronics component 106 can comprise one or more active or passive electronics components, such as resistors, transistors, integrated circuits, resistors, capacitors, etc., and combinations thereof.

Once the at least one electronics component 106 is attached to the substrate 102 and disposed in the cavity 110, a mold compound 118 can be deposited about the at least one electronics component 106 to fill the cavity 110 and cover the upper area of the substrate 102, as shown on FIG. 2. A plurality of solder contacts 120 can be attached to lower contact pads (e.g., 114b) of the through-substrate-vias 108a-n for attachment to an electronics assembly circuit board (which can occur at any point in the process of FIGS. 2-5).

As illustrated on FIG. 3, the mold compound 208 can be ground down by a grinding tool (not shown) or removed by other physical or chemical procedures to expose upper contact pads (e.g., 114a-n) of the through-substrate-vias 108a-n. Alternatively, the materials removal (e.g. grinding) can expose an upper end of the through-substrate-via 108a, and then the upper contact pads (e.g., 114a) can be formed (e.g., etched, etc.) accordingly.

As illustrated in FIG. 4, a second electronics package device 200 can be coupled to a top of the first electronics package device 100. Specifically, a solder ball array 210 of an appropriate pitch can be deposited along upper contact pads (e.g., 114a) of the through-substrate-vias 108a-n. As discussed above regarding FIGS. 1A and 1B, the solder ball array can maximize I/O contacts for attachment of the second electronics package device 200 because a pitch value (e.g., 0.015 mm) of each through-substrate-via 108a-n is independent of the height or thickness value (e.g., 0.1 to 1.0+ mm) of the first height region 104a of the substrate 102. This configuration of the solder balls 210 eliminates the need for a large amount or layer of solder between electronics device package 100 and electronics package device package 200 (except for the small solder balls 210 between respective contact pads).

The second electronics package device can be any device that is suitable for attachment to or use with the first electronics package device. In one example, the second electronics package device 200 comprises a plurality of electronic devices 206 (or at least one) supported by or coupled to a substrate 202 of the second electronics package device 200. A mold compound 218 can be deposited to encase the plurality of electronic devices 206. The plurality of electronic devices 206 can be a stack of dies, as shown. Alternatively, the plurality of electronic devices 206 can be one electronic device, such as a DRAM device, NAND device, memory device, power supply device, or other electronics component. The second electronics package device 200 can be separately formed and then later attached to the first electronics package device 100. In some embodiments, the first electronics package device 100 of FIG. 2 can be a final product device that is ready for testing/sorting and shipping to a manufacturer for separate/supplemental PoP attachment processes, such as described regarding FIGS. 4 and 5.

As illustrated on FIG. 5, the first and second electronics package devices 100 and 200 can be attached as a PoP device, and then the first electronics package device 100 can be bonded to an assembly circuit board 250 along the solder components 120 (through standard bonding processes). The through-substrate-vias discussed herein can be utilized for signal/power, whether directly from the assembly circuit board 250, or generated in package device 100. For instance, signals from the electronic components 106 can be routed through the substrate by horizontal interconnects that connect with one or more of the through-substrate-vias 108a-n.

The through-substrate-vias discussed herein provide manufacturing flexibility to support custom package combinations, such as package device 100 being a SSD device, and package device 200 can be additional DRAM, or NAND, or even an entire power delivery system.

Alternatively, the molding process of FIGS. 2 and 3 can be eliminated as described above, and the second electronics package device 200 can be attached to the first electronics package device 100. Once attached, then a mold compound can be flowed into (or otherwise deposited into) the cavity 110 of the substrate 102 and flowed around the attachment contacts (ball grid array) between the first and second electronics package devices 100 and 200.

FIG. 6 is a flow diagram illustrating a method 300 of making an electronics package device (e.g., 100) that minimizes space required for vertical interconnects for (PoP) devices, such as described above regarding FIGS. 1A-5. At operation 302, the method comprises forming a substrate (e.g., 102) having a plurality of through-substrate-vias (e.g., 108a-n) formed through the substrate. As also discussed above, at operation 304 the substrate can be formed by forming a plurality redistribution layers to build-up the substrate to form the through-substrate-vias each having a pitch value independent of a thickness value of the substrate (e.g., of a first height region 104a). Alternatively, at operation 306 the substrate can be formed by forming an organic substrate to forming the through-substrate-vias each having a pitch value independent of a thickness value of the substrate. At operation 308, the method comprises coupling at least one electronic component (e.g., die stack 106) to a cavity (e.g., 110) of the substrate. At operation 310, the cavity can be formed by forming the substrate to have a first height region and a second height region to define the cavity, such that the through-substrate-vias are formed through the first height region. At operation 312, the method comprises encasing the at least one electronic component with an encapsulate material (e.g., 118).

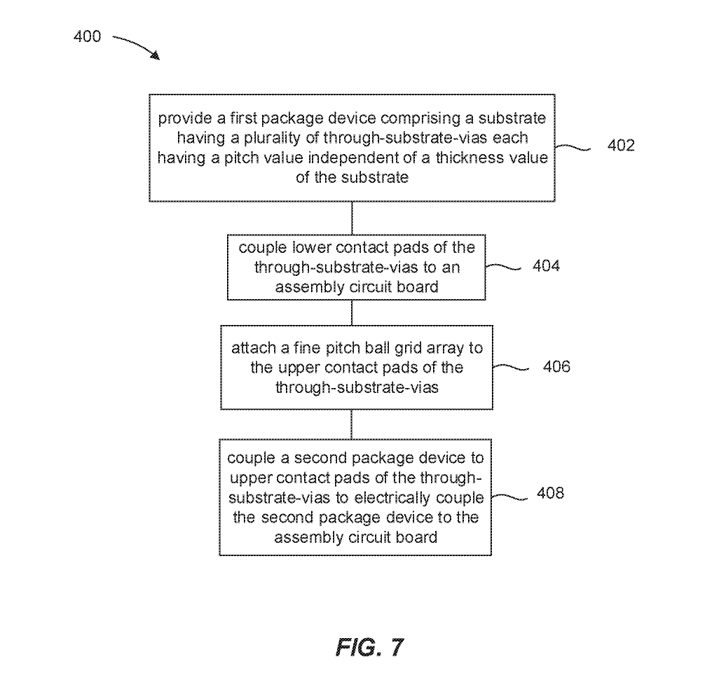

FIG. 7 is a flow diagram illustrating a method 400 for maximizing an amount of input/output contacts between an assembly circuit board and an electronics package device, such as described above regarding FIGS. 1A-5. At operation 402, the method comprises providing a first package device (e.g., 100) comprising a substrate having a plurality of through-substrate-vias (e.g., 108a-n) each having a pitch value independent of a thickness value of the substrate, such as described above regarding operations of method 300. At operation 404, the method comprises coupling lower contact pads (e.g., 114) of the through-substrate-vias to an assembly circuit board (e.g., 250). At operation 406, the method comprises attaching a fine pitch ball grid array (e.g., 210) to the upper contact pads of the through-substrate-vias. At operation 408, the method comprises coupling a second package device (e.g., 200) to upper contact pads of the through-substrate-vias to electrically couple the second package device to the assembly circuit board, as further detailed regarding FIGS. 4 and 5.

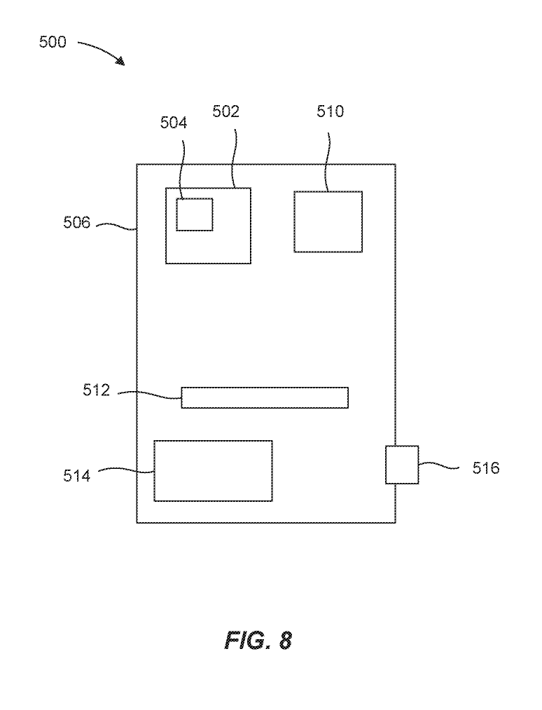

FIG. 8 illustrates an example computing system 500. The computing system 500 can include a PoP device 502 having an electronics package device 504 (e.g., such as package device 100 as disclosed above), coupled to a motherboard 506 (e.g., assembly circuit board 250). In one aspect, the computing system 500 can also include a processor 510, a memory device 512, a radio 518, a heat sink 514, a port 516, a slot, or any other suitable device or component, which can be operably coupled to the motherboard 506. The computing system 500 can comprise any type of computing system, such as a desktop computer, a laptop computer, a tablet computer, a smartphone, a server, etc. Other embodiments need not include all of the features specified in FIG. 8, and may include alternative features not specified in FIG. 8.

### EXAMPLES

The following examples pertain to further embodiments.

In one example there is provided an electronics package device having a through-substrate-via, comprising: a substrate comprising a first height region and a second height region, where the first height region has a thickness value greater than a thickness value of the second height region; at least one electronic component supported by the second height region; and a through-substrate-via disposed through the first height region. The through-substrate-via can have a pitch-to-height ratio of less than 1.5, wherein a pitch value of the through-substrate-via is independent of the thickness value of the first height region of the substrate.

In one example of the package device, the pitch value is less than 0.4 mm.

In one example of the package device, the pitch value is less than 0.2 mm.

In one example of the package device, the thickness value of the first height region is at least 0.1 mm.

In one example of the package device, the thickness value of the first height region is at least 0.5 mm.

In one example of the package device, the pitch-to-height ratio is less than 1.0.

In one example of the package device, the pitch-to-height ratio is less than 0.2.

In one example of the package device, the through-substrate-via has a substantially constant cross-sectional area along its entire length.

In one example of the package device, the through-substrate-via has a substantially uniform diameter along its entire length.

In one example of the package device, the substrate is formed by a redistribution layering process, such that the substrate comprises a plurality of redistribution layers that form the through-substrate-via.

In one example of the package device, the substrate is an organic substrate.

In one example of the package device, the electronics package device further comprises a plurality of through-substrate-vias disposed in through the first height region for electrically coupling a supplemental package device to an assembly circuit board.

In one example of the package device, the substrate comprises a cavity defined by the first and second height regions, and further comprising a plurality of electronic components stacked in the cavity.

In one example of the package device, the electronics package device further comprises a mold compound material encasing the plurality of electronic components in the cavity.

In one example of the package device, the plurality of electronic components comprises at least four dies stacked to each other.

In one example of the package device, the at least one electronic component comprises at least one of a passive electronic component and an active electronic component.

In one example of the package device, the through-substrate-via is vertically disposed through the first height region.

In one example there is provided an electronics assembly for PoP devices, comprising: an assembly circuit board; a first package device comprising a first substrate having a plurality of through-substrate-vias each having a pitch value independent of a thickness value of the substrate; and a second package device stacked on the first package device and electrically coupled to the assembly circuit board by the through-substrate-vias.

In one example of an electronics assembly, the through-substrate-vias each have a pitch-to-height ratio of less than 1.0.

In one example of an electronics assembly, the pitch-to-height ratio is less than 0.2.

In one example of an electronics assembly, the pitch value is less than 0.4 mm, and wherein the thickness value of the first height region is at least 0.1 mm.

In one example of an electronics assembly, the pitch value is less than 0.2 mm, and wherein the thickness value of the first height region is at least 0.5 mm.

In one example of an electronics assembly, each through-substrate-via has a substantially constant cross-sectional area along its entire length.

In one example of an electronics assembly, each through-substrate-via has a substantially uniform diameter along its entire length.

In one example of an electronics assembly, the first substrate is formed by a redistribution layering process, such that the first substrate comprises a plurality of redistribution layers that form the through-substrate-vias.

In one example of an electronics assembly, the first substrate comprises a cavity defined by a first height region and second height region, the first package device comprising a plurality of electronic components stacked in the cavity.

In one example of an electronics assembly, the electronics assembly further comprises a mold compound material that encases the plurality of electronic components.

In one example of an electronics assembly, the plurality of electronic components comprises at least one of a stack of dies, passive electronic components, active electronic components, and combinations thereof.

In one example of an electronics assembly, at least some of the through-substrate-vias are vertically disposed through the first height region of the first substrate.

In one example of an electronics assembly, the electronics assembly further comprises a fine pitch ball array disposed along tops of the through-substrate-vias and between the first and second package devices for electrically coupling the second package device to the assembly circuit board via the through-substrate-vias.

In one example of an electronics assembly, the second package device comprises at least one of DRAM device, NAND device, and memory device.

In one example there is provided a method of making an electronics package device that minimizes space required for vertical interconnects for PoP devices. The method comprises forming a substrate having a plurality of through-substrate-vias formed through the substrate, where each through-substrate-via has a pitch value independent of a thickness value of the substrate; coupling at least one electronic component to a cavity of the substrate; and encasing the at least one electronic component with an encapsulate material.

In one example of a method of making an electronics package device, forming the substrate comprises forming a plurality of redistribution layers to each other to build-up the substrate and form the through-substrate-vias such that each through-substrate-via has a pitch-to-height ratio of less than 1.0.

In one example of a method of making an electronics package device, forming the substrate comprises forming an organic substrate such that each through-substrate-via has a pitch-to-height ratio of less than 1.0.

In one example of a method of making an electronics package device, forming substrate comprising forming each through-substrate-via to have a substantially uniform diameter along the entire length of the through-substrate-via such that each through-substrate-via has a pitch value of less than 0.2 mm.

In one example of a method of making an electronics package device, forming the substrate comprises forming each through-substrate-via to have a pitch value of less than 0.2 mm and forming the substrate to have a thickness value of at least 0.5 mm.

In one example of a method of making an electronics package device, forming the substrate further comprises forming a first height region and a second height region to define the cavity, such that the through-substrate-vias are formed through the first height region.

In one example of a method of making an electronics package device, the method further comprises coupling a plurality of electronic components into the cavity prior to encasing the plurality of electronic components.

In one example, there is provided a method for maximizing an amount of input/output contacts between an assembly circuit board and an electronics package device. The method comprises providing a first package device comprising a substrate having a plurality of through-substrate-vias each having a pitch value independent of a thickness value of the substrate; coupling lower contact pads of the through-substrate-vias to an assembly circuit board; and coupling a second package device to upper contact pads of the through-substrate-vias to electrically couple the second package device to the assembly circuit board.

In one example of a method for maximizing an amount of input/output contacts between and assembly circuit board and an electronics package device, the method further comprises coupling a plurality of electronic components to the substrate prior to coupling the second package device to the through-substrate-vias.

In one example of a method for maximizing an amount of input/output contacts between and assembly circuit board and an electronics package device, the method further comprises encapsulating the plurality of electronic components with an encapsulate material.

In one example of a method for maximizing an amount of input/output contacts between and assembly circuit board and an electronics package device, the method further comprises grinding the encapsulate material prior to coupling the second package device to the through-substrate-vias.

In one example of a method for maximizing an amount of input/output contacts between and assembly circuit board and an electronics package device, the method further comprises encapsulating at least one electronic component of the second package with the encapsulate material.

In one example of a method for maximizing an amount of input/output contacts between and assembly circuit board and an electronics package device, providing the first package device comprises forming a plurality of redistribution layers to build-up the substrate and form the through-substrate-vias such that each through-substrate-via has a pitch-to-height ratio of less than 1.0.

In one example of a method for maximizing an amount of input/output contacts between and assembly circuit board and an electronics package device, providing the first package device comprises forming an organic substrate such that each through-substrate-via has a pitch-to-height ratio of less than 1.0.

In one example of a method for maximizing an amount of input/output contacts between and assembly circuit board and an electronics package device, providing the first package device comprises forming each through-substrate-via to have a substantially uniform diameter along the entire length of the through-substrate-via such each through-substrate-via has a pitch value of less than 0.2 mm.

In one example of a method for maximizing an amount of input/output contacts between and assembly circuit board and an electronics package device, the method further comprises attaching a fine pitch ball grid array to the upper contact pads of the through-substrate-vias prior to coupling the second package device to the first package device.

In one example of a method for maximizing an amount of input/output contacts between and assembly circuit board and an electronics package device, the method further comprises coupling at least one of DRAM device, NAND device, and memory device to a substrate of the second package device.

In one example of a method for maximizing an amount of input/output contacts between and assembly circuit board and an electronics package device, providing the first package device comprises forming the through-substrate-vias to each have a pitch-to-height ratio of less than 0.2.

In one example of a method for maximizing an amount of input/output contacts between and assembly circuit board and an electronics package device, providing the first package device comprises forming the through-substrate-vias to each have a pitch value of less than 0.4 mm and a forming the substrate to have a thickness value of at least 0.5 mm.

In one example there is provided, an electronics package device, comprising: a substrate having a top surface, a bottom surface, and a cavity; a plurality of dies coupled to the substrate and stacked in the cavity; and a through-substrate-via disposed through the substrate extending from the top surface to the bottom surface, wherein the plurality of dies stacked in the cavity does not intersect a plane defined by the top surface.

In one example of an electronics device package, the through-substrate-via has a substantially constant cross-sectional area along its entire length.

In one example of an electronics package, the through-substrate-via has a substantially uniform diameter along its entire length.

In one example of an electronics package, the package further comprising a plurality of through-substrate-vias disposed in through a first height region of the substrate, wherein a second height region of the substrate supports the plurality of dies.

In one example of an electronics package, the plurality of dies comprise at least four dies.

Circuitry used in electronic components or devices (e.g., a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

While the forgoing examples are illustrative of the specific embodiments in one or more particular applications, it will be apparent to those of ordinary skill in the art that numerous modifications in form, usage and details of implementation can be made without departing from the principles and concepts articulated herein.

What is claimed is:

1. An electronics package device, comprising:
a substrate having a first height region and a second height region, the first height region having a thickness value greater than a thickness value of the second height region;
a cavity defined by the first and second height regions;
a plurality of electronic components stacked in the cavity; and
a plurality of through-substrate vias disposed through the first height region and having upper contact pads for electrically coupling a supplemental package device to an assembly circuit board supporting the substrate, each through-substrate-via having a pitch-to-height ratio of less than 1.5, wherein a pitch value of each through-substrate-via is independent of the thickness value of the first height region of the substrate.

2. The electronics package device of claim 1, wherein the pitch value is less than 0.4 mm.

3. The electronics package device of claim 1, wherein the thickness value of the first height region is at least 0.1 mm.

4. The electronics package device of claim 1, wherein the pitch-to-height ratio is less than 1.0.

5. The electronics package device of claim 1, wherein each through-substrate-via has a substantially constant cross-sectional area along its entire length.

6. The electronics package device of claim 1, wherein each through-substrate-via has a substantially uniform diameter along its entire length.

7. The electronics package device of claim 1, wherein the substrate is formed by a redistribution layering process.

8. The electronics package device of claim 1, wherein the substrate is an organic substrate.

9. The electronics package device of claim 1, wherein the upper contact pads of the plurality of through-substrate-vias are configured to be electrically coupled to a supplemental substrate of the supplemental package device including one or more dies.

10. The electronics package device of claim 1, wherein the substrate comprises a top surface and a bottom surface, the bottom surface supporting a plurality of lower contact pads of the through-substrate-vias coupleable to the assembly circuit board, and the top surface supporting the plurality of upper contact pads of the through-substrate-vias, and wherein the cavity extends from the top surface of the substrate.

11. The electronics package device of claim 1, further comprising a mold compound material encasing the plurality of electronic components in the cavity.

12. The electronics package device of claim 1, wherein the plurality of electronic components comprises at least four dies stacked to each other.

13. The electronics package device of claim 1, wherein the thickness value of the first height region is greater than a combined thickness value of the second height region and the plurality of electronic components.

14. The electronics package device of claim 1, wherein a top surface of the first height region defines a plane that is spatially separated from a plane defined by a top surface of the plurality of electronic components.

15. The electronics package device of claim 1, wherein a top surface of the first height region defines a plane that aligns with a plane defined by a top surface of the plurality of electronic components.

16. The electronics package device of claim 1, wherein the at least one electronic component comprises at least one of a passive electronic component and an active electronic component.

17. The electronics package device of claim 1, wherein the through-substrate-via is vertically disposed through the first height region.

18. An electronics assembly for package-on-package (PoP) devices, comprising:
an assembly circuit board;
a first package device comprising a first substrate having a bottom surface and a top surface, and having a plurality of through-substrate-vias each having a pitch value independent of a thickness value of the substrate, wherein a plurality of lower contacts of the through-substrate-vias are attached to the assembly circuit board about the bottom surface of the first substrate, the first substrate comprising a cavity that extends from the top surface of the first substrate, wherein a plurality of electronic components is stacked the cavity; and
a second package device stacked on the top surface of the first substrate of the first package device and electrically coupled to the assembly circuit board by the through-substrate-vias.

19. The electronics assembly of claim 18, wherein the through-substrate-vias each have a pitch-to-height ratio of less than 1.0.

20. The electronics assembly of claim 18, wherein the pitch value is less than 0.4 mm, and wherein the thickness value of the first height region is at least 0.1 mm.

21. The electronics assembly of claim 18, wherein the second package device comprises a second substrate supported by the top surface of the first substrate, and comprises at least one die supported by the second substrate.

22. The electronics assembly of claim 21, further comprising a fine pitch ball array disposed along tops of the through-substrate-vias and between the first and second package devices for electrically coupling the second package device to the assembly circuit board via the substrate-through-vias.

23. A method of making an electronics package device that minimizes space required for vertical interconnects for package-on-package (PoP) devices, comprising;
forming a substrate having a plurality of through-substrate-vias formed through the substrate, each through-substrate-via having a pitch value independent of a thickness value of the substrate, the through-substrate-vias having upper contact pads for electrically coupling a supplemental package device to an assembly circuit board;
coupling at least one electronic component to a cavity of the substrate; and
encasing the at least one electronic component with an encapsulate material to form a package device.

24. The method of claim 23, wherein forming the substrate comprises forming a plurality of redistribution layers to each other to build-up the substrate and form the through-substrate-vias such that each through-substrate-via has a pitch-to-height ratio of less than 1.0.

25. The method of claim 23, wherein forming the substrate comprises forming an organic substrate such that each through-substrate-via has a pitch-to-height ratio of less than 1.0.

26. The method of claim 23, wherein forming the substrate further comprises forming a first height region and a second height region to define the cavity, such that the through-substrate-vias are formed through the first height region, and further comprising coupling a plurality of electronic components to the second height region in the cavity prior to encasing the plurality of electronic components.

27. The method of claim 26, wherein a top surface of the first height region defines a plane that is spatially separated from a plane defined by a top surface of the plurality of electronic components.

28. The method of claim 27, wherein a top surface of the first height region defines a plane that aligns with a plane defined by a top surface of the plurality of electronic components.
